(19) United States
(12) Patent Application Publication
(10) Pub. No.: US 2008/0099835 A1
(43) Pub. Date: May 1, 2008

(54) Exposure Mask and Method for Forming A Gate Using the Same

(75) Inventor: Jin Soo Kim, Icheon-Si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyeonggi-do (KR)

(21) Appl. No.: 11/771,405

(22) Filed: Jun. 29, 2007

(30) Foreign Application Priority Data
Oct. 31, 2006 (KR) 10-2006-106162

(51) Int. Cl. H01L 29/78; G03F 1/00; H01L 21/3205

(52) U.S. Cl. 257/330; 430/5; 438/589; 257/E21.249; 257/E29.262

(57) ABSTRACT

An exposure mask and a method for forming a gate using the same are provided. A recess is formed by using a recess exposure mask with an isolated light transmitting pattern so that the recess may be formed only on an active region, and an edge of the active region is protected from damage during a recess forming process. Accordingly, production time and expense are reduced, yet device productivity is improved.

### CROSS-REFERENCE TO RELATED APPLICATION

The priority of Korean patent application number 10-2006-106162, filed on Oct. 31, 2006, the entire disclosure of which are incorporated herein by reference, is claimed.

### BACKGROUND OF THE INVENTION

The invention relates in general to an exposure mask and a method for forming a gate using the same. More particularly, the invention relates to technology for forming a recess with a recess exposure mask having an isolated light transmitting pattern, so that the recess may be formed on an active region, and an edge of the active region may be protected from damage during a recess forming process. As a consequence, production time and expense are reduced, yet the productivity of the process and resulting devices is improved.

As gate linewidths of semiconductor devices become narrower, a recess gate, a fin gate, and a bulb gate are introduced to meet production demands.

When the recess gate is used, a recess pattern exposing a recess gate region is formed prior to the formation of a gate. With the recess pattern as a mask, an active region of a semiconductor substrate is etched to a designated depth to form a recess. Finally, a gate is formed on an upper part of the recess.

The recess gate with the above structure can increase the channel length.

However, a problem associated with the narrower gate linewidth is that recess gates formed in non-active regions must be removed to improve the properties and productivity of the resulting devices.

FIGS. 1a and 1b show a layout view of a semiconductor device having a defined recess gate region according to a conventional technique and illustrates the problems accompanying the conventional technique.

Referring to FIG. 1a, there is a semiconductor substrate having an active region 110 and a device isolation region 120. A photoresist pattern 130 defining a recess gate region 140 in a line/space form is provided in a direction perpendicular to the major axis of the active region 110.

Next, an etching process is carried out using the photoresist pattern 130 as a mask to form a recess.

Unfortunately, while etching a recess to be formed in a region adjacent to an outward edge of the active region 110, the edge may be damaged by the etching process.

FIG. 1b is an SEM (scanning electron microscope) picture of an edge of the active region having defects shaped like a letter ‘A’ after the recess gate is formed.

According to the conventional exposure mask and the method for forming a gate using the same, a passing gate that passes outside of the edge of an active region during a recess gate forming process partially overlaps with a damaged edge portion of the active region, and this causes device properties to deteriorate.

To avoid this problem, a hard mask layer may be used to cover or mask non-active regions during the recess forming process. However, this only adds hard mask layer deposition and etching processes and increases the complexity of the overall procedure.

### SUMMARY OF THE INVENTION

In view of foregoing, the invention provides an exposure mask and a method for forming a gate using the same, in which a recess is formed by using a recess exposure mask with an isolated light transmitting pattern, so that the recess may be formed only on an active region, and an edge of the active region is protected from damage during a recess forming process. This reduces production time and expense, while increasing device productivity.

To achieve the foregoing, the invention an exposure mask used to form a recess gate of a semiconductor device including a device isolation region and an active region having a major axis and a minor axis, the exposure mask including: a transparent substrate; and a plurality of light transmitting patterns each having a major axis and a minor axis and each being disposed on the transparent substrate, wherein adjacent light transmitting patterns are isolated from each other in a direction perpendicular to the major axis of the active region, and at least two light transmitting patterns pass across one active region.

In other aspect, the semiconductor device comprising: A active region; and a recess gate region over one active region, wherein the recess gate regions are not overlapping with another active region.

In the other aspect, the invention provides a gate forming method, including the steps of: forming an etching mask layer over a semiconductor substrate including a device isolation film and an active region having a major axis; and patterning the etching mask layer using a mask defining an isolated gate region extending in a direction perpendicular to the major axis of the active region.

A recess is formed using a recess exposure mask having an isolated light transmitting pattern and thus, a recess gate may be formed only on an active region. Accordingly, the active region's edges can be protected from possible damage during a recess gate forming process, and leads to an increase in device productivity.

Furthermore, the invention makes it possible to form a recess gate without the need for further processing to the conventional method.

Other objectives and advantages of the invention will be understood by the following description and will also be appreciated by the embodiments of the invention more clearly. Further, the objectives and advantages of the invention will readily be seen that they can be realized by the means and combination specified in the claims.

### BRIEF DESCRIPTION OF THE DRAWINGS

FIGS. 1a and 1b show a layout view of a semiconductor device having a defined recess gate region according to a conventional technique and a picture showing the problems accompanying the conventional technique;

FIGS. 2a and 2b are layout views of simulation images of a recess gate exposure mask according to a preferred embodiment of the invention;

FIG. 3 is a layout view of a semiconductor device having a recess gate region according to a preferred embodiment of the invention; and

FIGS. 4a through 4c are cross-sectional views illustrating the steps of a method for forming a recess gate according to a preferred embodiment of the invention.

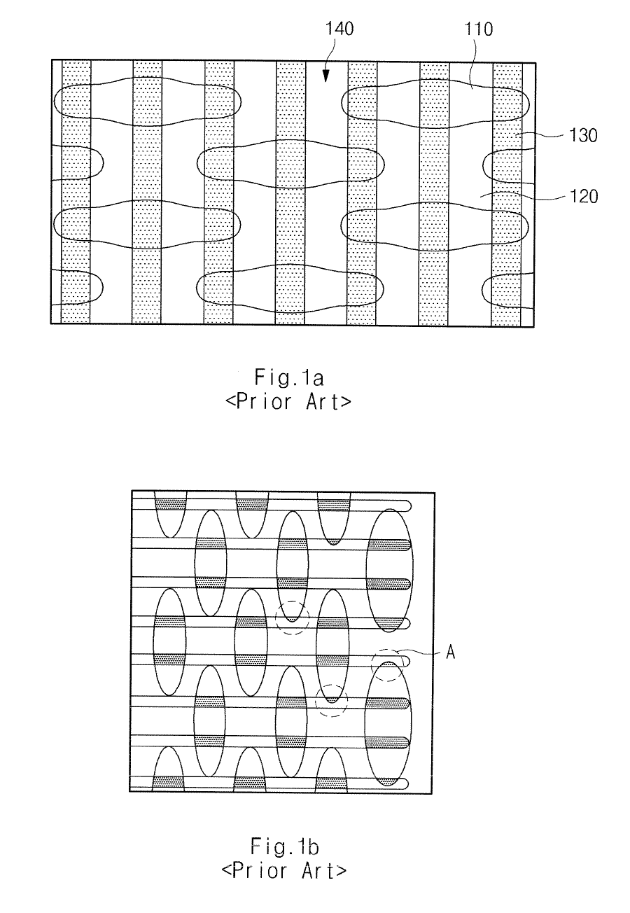

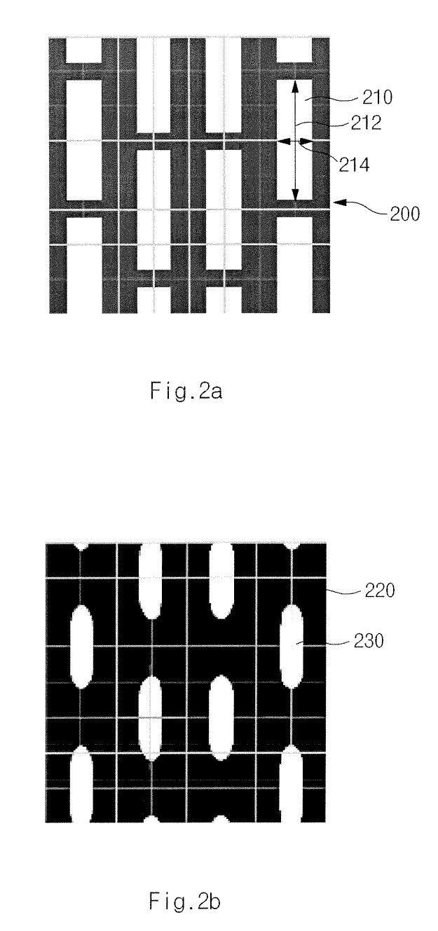

### DESCRIPTION OF SPECIFIC EMBODIMENTS

Hereinafter, preferred embodiments of the invention are set forth in detail with reference to the accompanying drawings so that those skilled in the art can easily carry out the invention.

FIGS. 2a and 2b are layout views of simulation images of a recess gate exposure mask according to a preferred embodiment of the invention.

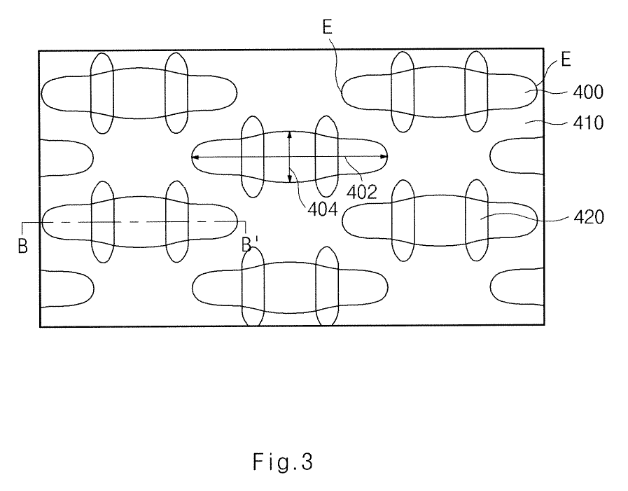

Referring to the layout view of a recess gate exposure mask 200 in FIG. 2a, a plurality of isolated light transmitting patterns 210 extend in a direction perpendicular to a major axis of an active region (e.g., along line B-B′ as illustrated in FIG. 3).

Each light transmitting pattern 210 has a major axis 212 along its length and a minor axis 214 across its width. At this time, a line width of the major axis 212 of the light transmitting pattern 210 preferably is greater than the line width of a minor axis 404 of the active region (See FIG. 3).

Each light transmitting pattern 210 occupies a discrete region, for example being the light transmitting patterns 210 are overlapping with another active region. Desirably, two light transmitting patterns 210 are formed on one active region in a facially opposed manner.

FIG. 2b presents a simulation image of the recess gate pattern formed of using of the exposure mask 200 shown in FIG. 2a.

When a developing process is carried out after a photoresist is exposed with the exposure mask, a region having the light transmitting pattern (210 in FIG. 2a) is expected to have a resulting recess gate pattern 230 of oblong shape on a substrate 220.

At this time, the exposing process used with the recess gate exposure mask of the invention has the same numerical aperture (NA) and the same sigma of an exposure condition as in a conventional recess gate exposure mask in line/space form. However, the resulting margin for both depth of focus (DOF) and exposure latitude are enhanced.

FIG. 3 diagrammatically illustrates a gate forming method using an exposure mask of the invention.

As is apparent from the drawing, a semiconductor substrate has an active region 400 and a device isolation region 410, both of which are partially overlapped by a recess gate region 420. Each active region 400 has a major axis 402 along its length and a minor axis 404 across its width.

Here, the recess gate region 420 has an oblong shape extending in a perpendicular direction to the major axis 402 of the active region 400, and a plurality of recess gate regions 420 are formed over one active region 400.

Each recess gate region 420 occupies a discrete region, for example being separated from neighboring recess gate regions 420 by a given distance. Unlike the conventional recess gate region in a line/space form, the recess gate regions according to the invention are formed only near a central portion of the active region 400, without overlapping the edges of the active region 400. More specifically, the recess gate regions 420 do not overlay/are not located near terminal points/edges E of the active region 400, wherein the terminal points/edges E are located in the area where the boundary of the active region 400 is intersected by is major axis. This structure may prevent the active region's edges from being damaged during a recess forming process.

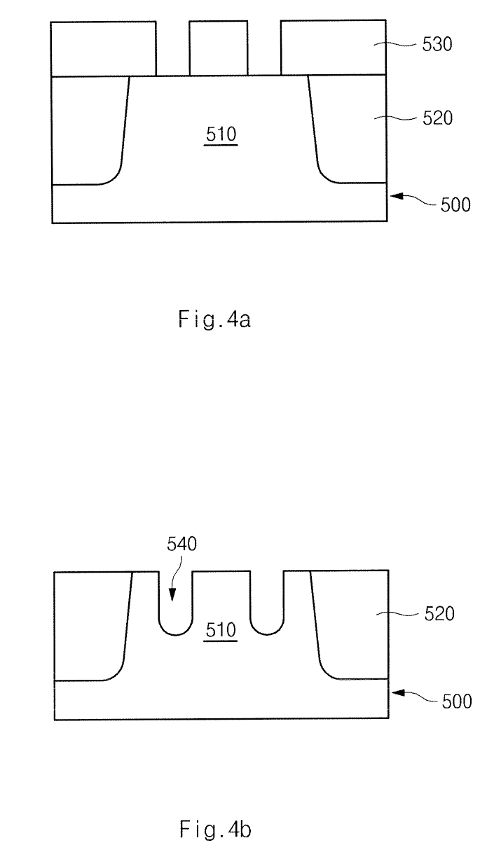

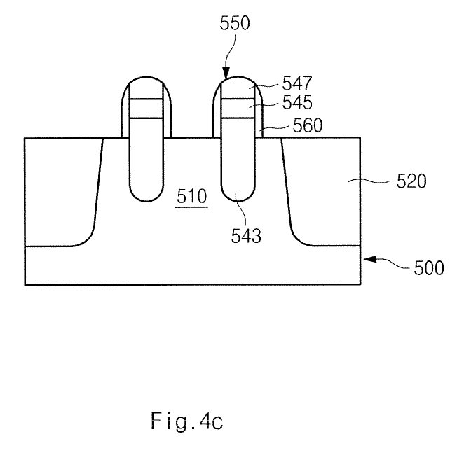

FIGS. 4a through 4c are cross-sectional views illustrating the steps of a gate forming method using an exposure mask according to the invention. In particular, these cross-sectional views are taken along cut plane B-B′ of FIG. 3, which also coincides with a major axis of its respective active region 400.

Referring to FIG. 4a, a hard mask layer (not shown) used as an etching mask layer and a photoresist (not shown) are formed on an upper part of a semiconductor substrate 500 including an active region 510 and a device isolation film 520.

Next, exposing and developing processes are carried out, using a recess gate exposure mask according to the disclosure (FIG. 2a) with an isolated light transmitting pattern formed in a direction perpendicular to the major axis and aligned with the minor axis of the active region 510 (i.e., analogous to axes 402 and 404, respectively, of the active region 400 in FIG. 3), thus forming a photoresist pattern (not shown).

Here, the exposing process for forming the photoresist pattern is preferably carried out using a crosspole illuminator.

Next, the hard mask layer is etched using the photoresist pattern as a mask to form a hard mask layer pattern 530 by any suitable means. Following the formation of the hard mask layer pattern 530, the photoresist pattern is removed by any suitable means.

At this time, the hard mask layer pattern 530 is formed in such a manner to expose isolated recess gate regions on the active region 510.

Referring to FIG. 4b, using the hard mask layer pattern 530 as a mask, the active region 510 of the semiconductor substrate 500 is etched to a preset depth to form a recess 540. Then the hard mask layer pattern 530 is removed.

The recess 540 is formed on the active region 510. Desirably, two recesses are formed over one active region 510.

Referring to FIG. 4c, a gate pattern 550 is formed on an upper part of the recess 540, and a spacer 560 is formed on both sides of the gate pattern 550. The spacer 560 preferably includes of a nitride film.

Preferably, the gate pattern 550 has a laminated structure made up of a gate polysilicon layer 543, a gate metal layer 545, and a gate hard mask layer 547.

Because the recess is formed only on the active region 510, edges of the active region 510 are protected from damage.

The above embodiments of the invention are illustrative and not limiting. Various alternatives and equivalents are possible. The invention is not limited by the type of deposition, etching polishing, and patterning steps described herein. Nor is the invention limited to any specific type of semiconductor device. For example, the invention may be implemented in a dynamic random access memory (DRAM) device or nonvolatile memory device. Other additions, subtractions, or modifications that are obvious in view of the disclosure and are intended to fall within the scope of the appended claims.

What is claimed is:

1. An exposure mask useful for forming a recess gate of a semiconductor device comprising a device isolation region and an active region having a major axis and a minor axis, the exposure mask comprising:
a transparent substrate; and
a plurality of light transmitting patterns each having a major axis and a minor axis and each being disposed on the transparent substrate, wherein adjacent light transmitting patterns are isolated from each other in a direction perpendicular to the major axis of the active region, and at least two light transmitting patterns pass across one active region.

2. The exposure mask of claim 1, wherein a line width of each light transmitting pattern along its major axis is greater than the width of the active region along its minor axis.

3. The exposure mask of claim 1, wherein the light transmitting patterns are not over lapping with another active region.

4. A semiconductor device comprising:
An active region; and
A plurality of recess gate region, wherein the recess gate regions are not overlapping with another active region.

5. A gate forming method, comprising the steps of:
forming an etching mask layer over a semiconductor substrate comprising a device isolation film and an active region having a major axis; and
patterning the etching mask layer using a mask defining an isolated gate region extending in a direction perpendicular to the major axis of the active region.

6. The method of claim 5, further comprising the step of: etching a portion of the semiconductor substrate using the patterned etching mask layer as a mask, thereby forming a recess.

7. The method of claim 5, wherein the etching mask layer comprises a stacked structure comprising a hard mask layer and a photoresist.

8. The method of claim 7, wherein the step of patterning the etching mask layer further comprises performing an exposure process on the photoresist using a crosspole illuminator, thereby forming a photoresist pattern.

9. The method of claim 6, wherein the step of etching a portion of the semiconductor substrate further comprises forming two recesses over one active region.

10. The method of claim 7, further comprising the steps of:
removing the hard mask layer; and
forming a gate over the semiconductor substrate.

11. A gate forming method, comprising the steps of:
forming an etching mask layer over a semiconductor substrate comprising an active region and a device isolation film; and
patterning the etching mask layer using the exposure mask of claim 1.
